(19) United States
(12) Patent Application Publication
(10) Pub. No.: US 2011/0207290 A1
(43) Pub. Date: Aug. 25, 2011

(54) SEMICONDUCTOR DEVICE FABRICATION METHOD

(75) Inventor: Hidetomo Nishimura, Miyagi (JP)

(73) Assignee: OKI SEMICONDUCTOR CO., LTD., Tokyo (JP)

(21) Appl. No.: 13/017,507

(22) Filed: Jan. 31, 2011

(30) Foreign Application Priority Data
Feb. 22, 2010 (JP) 2010-035921

(51) Int. Cl. H01L 21/76

(52) U.S. Cl. 438/435; 257/E21.54

(57) ABSTRACT

A semiconductor device fabrication method deposits a dielectric stress-canceling film on oxide films formed on the surfaces of a semiconductor substrate and its isolation trenches, and partly etches the dielectric stress-canceling film to leave a dielectric base film inside each trench and a dielectric top film outside each trench. The trenches are then filled with a dielectric layer that covers the dielectric top and base films, the upper part of this dielectric layer is removed to expose the dielectric top films, and the dielectric top films are selectively etched, using the trench-filling dielectric layer as an etching mask. In the resulting trench isolation structure, the trenches are completely filled with dielectric material, and stress exerted by the oxide films in the trenches during heat treatment is canceled by opposing stress exerted by the dielectric base films.

### BACKGROUND OF THE INVENTION

1. Field of the Invention

The present invention relates to a semiconductor device fabrication method, more particularly to a method of forming an isolation structure.

2. Description of the Related Art

Because of the shrinking feature sizes of modern semiconductor devices, shallow trench isolation (STI) is now used for electrical isolation of their active regions. In STI, isolation trenches are formed in the device substrate and are filled with dielectric material. The published literature on STI technology includes U.S. Pat. No. 6,486,517 to Park and Japanese Patent Application Publications No. 2005-328049 (Kang at al.) and 2008-084899 (Morioka).

A conventional trench isolation process will be described with reference to the schematic sectional views in FIGS. 1 to 5. This process forms isolation trenches in a silicon substrate denoted by reference characters 210 after trench formation and 210B before trench formation. First, a silicon oxide film 220 and silicon nitride film 230 are sequentially formed on the substrate 201B (FIG. 1). Next, a resist mask (not shown) is formed on the silicon nitride film 230 by photolithography, and the silicon nitride film 230, silicon oxide film 220, and silicon substrate 201 are sequentially etched through the mask to form a pattern of isolation trenches 201a, 201b, 201c, 201d (FIG. 2). To repair damage caused by the etching process, the inner surfaces of the trenches 201a to 201d are thermally oxidized to form thin oxide films 241, 242, 243, 244 (FIG. 3).

Next, a chemical vapor deposition (CVD) process is used to deposit a layer of a dielectric material such as silicon oxide on the entire structure, filling the trenches 201a-201d, and a chemical mechanical polishing or chemical mechanical planarization (CMP) process is used to remove excess dielectric material and expose the remaining silicon nitride films 231, 232, 233, 234, 235 (FIG. 4), leaving dielectric layers 251A, 252A, 253A, 254A in the trenches. The silicon nitride films 231-235 act as CMP stopper films. The trench isolation structure is completed by removing the silicon nitride films 231-235 and the underlying silicon oxide films 221-225 by separate wet etching processes to expose the silicon substrate 201, leaving the trenches filled with planarized dielectric layers 251-254 (FIG. 5).

The subsequent processes carried out to form semiconductor circuit elements include heat treatment steps. During heat treatment, the thermal oxide films 241-244 that remain in the isolation trenches exert a strong compressive stress on the silicon substrate 201. As shown in FIG. 6, such stress can cause crystal defects 261, 262, 263 to develop from the interface between the silicon substrate 201 and the thermal oxide films 241-244. These defects 261-263 become current leakage paths that degrade device performance and lead to lower production yields.

### SUMMARY OF THE INVENTION

An object of the present invention is to form a trench isolation structure that provides full isolation performance and prevents the formation of crystal defects during heat treatment in subsequent semiconductor device fabrication steps.

The invention provides a semiconductor device fabrication method that forms a surface oxide film on a major surface of a semiconductor substrate, forms a trench by patterning the surface oxide film and substrate, and forms a thermal oxide film on the inner surfaces of the trench. A dielectric stress-canceling film is deposited on the surface oxide film and the thermal oxide film. The dielectric stress-canceling film is partly etched to leave a dielectric base film inside the trench and a dielectric top film outside the trench. A trench-filling dielectric layer is deposited, covering the dielectric base film and the dielectric top film. The upper part of the trench-filling dielectric layer is removed to expose the dielectric top film and the dielectric top film is selectively etched, using the remaining trench-filling dielectric layer as an etching mask. An isolation structure is thereby formed that includes the trench, its thermal oxide film, the dielectric base film, and the trench-filling dielectric layer.

In subsequent heat treatment, the thermal oxide film exerts stress on the semiconductor substrate, but the dielectric base film exerts a canceling stress that prevents crystal defects from developing at the interface between the substrate and the thermal oxide film and spreading into the substrate.

In addition, since the trench-filling dielectric layer covers the dielectric base film, the dielectric base film is not etched when the dielectric top film is etched. The trench is therefore left completely filled with dielectric material, and the trench isolation structure gives full isolation performance.

### BRIEF DESCRIPTION OF THE DRAWINGS

In the attached drawings:

FIGS. 1 to 5 are sectional views schematically illustrating steps in the fabrication of a conventional isolation structure;

FIG. 6 schematically illustrates the conventional isolation structure;

FIGS. 7 to 15 are sectional views schematically illustrating steps in the fabrication of an isolation structure according to a first embodiment of the invention;

FIGS. 16 to 20 are sectional views schematically illustrating steps in the fabrication of an isolation structure according to a comparative example; and

FIGS. 21 to 29 are sectional views schematically illustrating steps in the fabrication of an isolation structure according to a second embodiment of the invention.

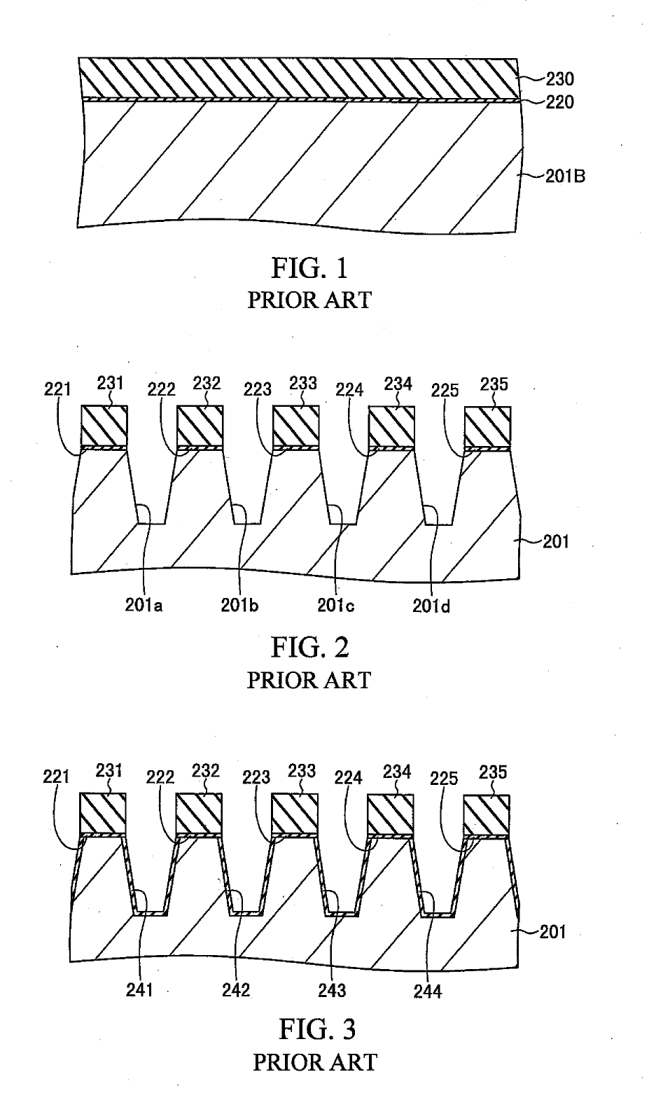

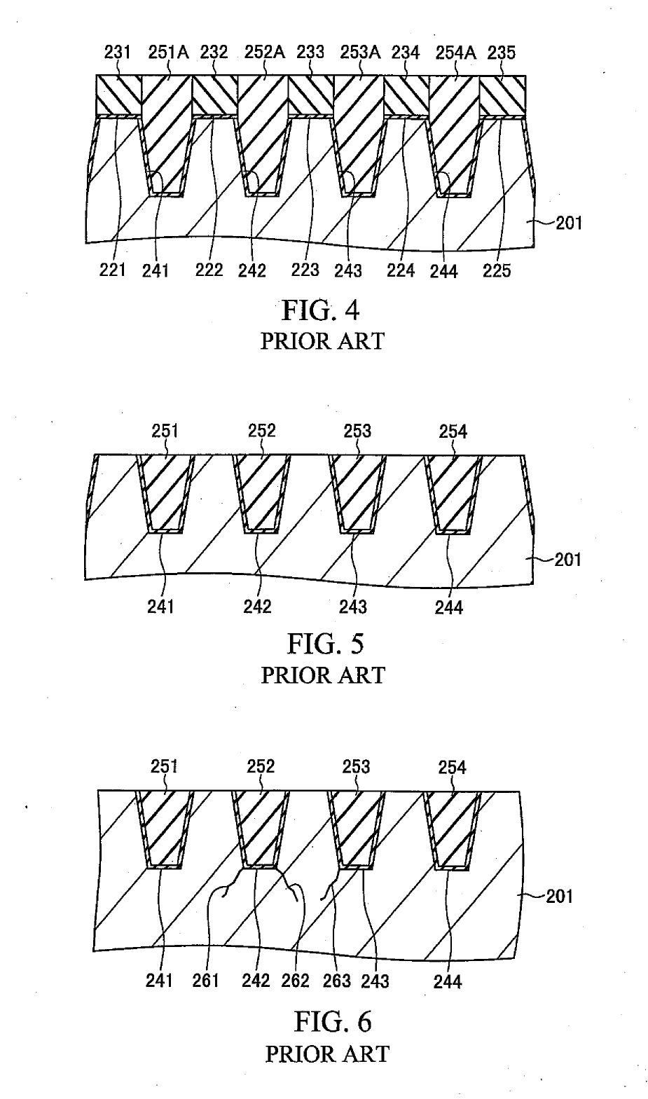

### DETAILED DESCRIPTION OF THE INVENTION

Embodiments of the invention will now be described with reference to the attached drawings, in which like elements are indicated by like reference characters. The embodiments form trench isolation structures on a silicon substrate denoted by reference characters 10 after trench formation and 10B before trench formation. It will be appreciated that various alternative substrates may be used, such as a monocrystalline semiconductor substrate of a non-silicon material, a polycrystalline semiconductor substrate, a compound semiconductor substrate, or a silicon-on-insulator (SOI) substrate.

### First Embodiment

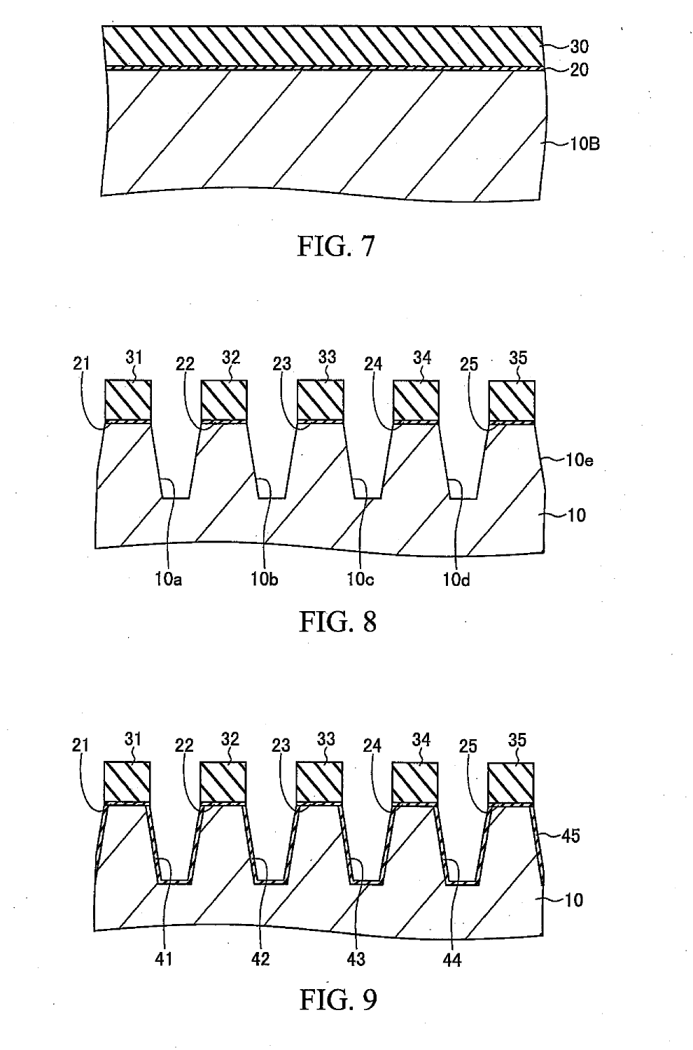

The first embodiment fabricates an isolation structure by the steps illustrated in FIGS. 7 to 15.

Referring to FIG. 7, first, a surface oxide film 20 and an intermediate dielectric film 30 are formed on a major surface of the silicon substrate 10B. The surface oxide film 20 may be formed by thermally oxidizing the major surface of the silicon substrate 10B, as is well known. The intermediate dielectric film 30 may be, for example, a nitride film (e.g., a silicon nitride film) formed by low-pressure chemical vapor deposition (LP-CVD). The thickness of the intermediate dielectric film 30 may be from approximately fifty to approximately two hundred nanometers (50-200 nm).

Next, a resist mask (not shown) is formed on the intermediate dielectric film 30 by a lithography process, such as photolithography or more specifically ultraviolet lithography, and the intermediate dielectric film 30, surface oxide film 20, and silicon substrate 10B are patterned by dry etching through the mask. As shown in FIG. 8, the intermediate dielectric film 30 and surface oxide film 20 are dissected into patterned intermediate dielectric films 31, 32, 33, 34, 35 and patterned surface oxide films 21, 22, 23, 24, 25, and isolation trenches 10a, 10b, 10c, 10d, 10e are formed in the silicon substrate 10.

Next, the inner walls of the trenches 10a-10e are thermally oxidized, forming respective thermal oxide films 41, 42, 43, 44, 45 (FIG. 9), in order to repair damage on the inner walls of the trenches 10a to 10e caused by the dry etching process. As noted above, in subsequent heat treatment, strong compressive stress may occur at the interfaces between the silicon substrate 10 and the thermal oxide films 41-45, due to the difference between their thermal expansion coefficients. For example, if heat treatment is carried out at a temperature over 900° C., the thermal oxide films 41-45 may exert compressive stresses of approximately two hundred to three hundred megapascals (200-300 MPa) on the silicon substrate.

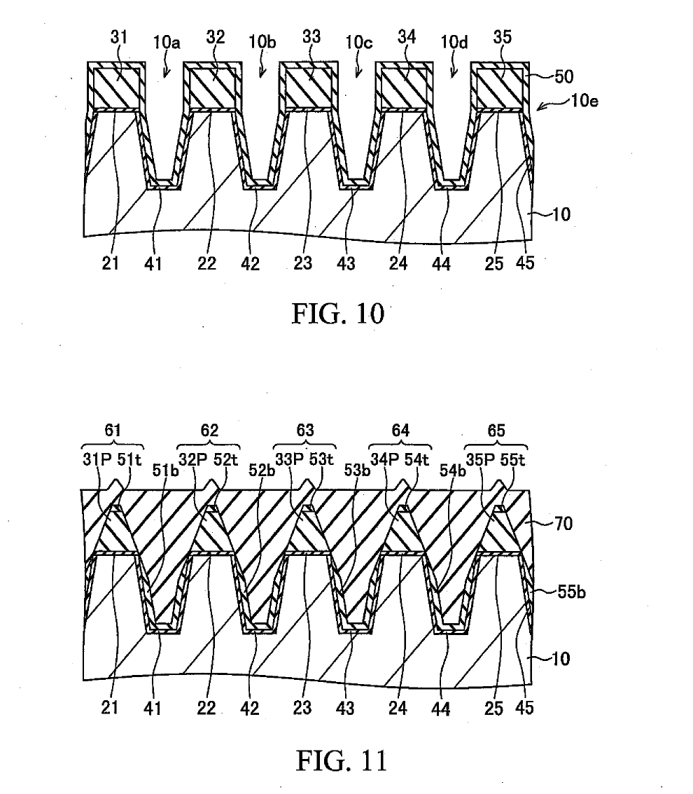

Next, a nitride film 50 with a thickness of approximately 20 nm to 100 nm is deposited as a dielectric stress-canceling film over all the intermediate dielectric films 31 to 35 and thermal oxide films 41-45 by LP-CVD (FIG. 10). During subsequent heat treatment, where this nitride film 50 makes contact with the thermal oxide films 41-45, it creates a tensile stress in a direction that cancels the compressive stress created by the thermal oxide films 41-45. An LP-CVD silicon nitride film formed as the stress-canceling nitride film 50 can exert a tensile stress of approximately 500 MPa to one gigapascal (1 GPa) during heat treatment, which is sufficient to prevent the occurrence of crystal damage originating at the interfaces between the thermal oxide films 41-45 and the silicon substrate 10 during the heat treatment.

Next, a trench-filling dielectric layer 70 is deposited on the entire major surface of the substrate, including the insides of the trenches 10a-10e in FIG. 10, by high-density plasma CVD (HDP-CVD). The trench-filling dielectric layer 70 may be a plasma oxide material or more generally any material with a high dielectric constant. The plasma deposition process also sputters or dry-etches the dielectric films 31-35 and 50 in a direction substantially perpendicular to the major surface of the silicon substrate 10. The remaining parts of the stress-canceling nitride film 50 are left as dielectric base films 51b, 52b, 53b, 54b, 55b inside the trenches 10a-10e and dielectric top films 51t, 52t, 53t, 54t, 55t outside the trenches 10a-10e (FIG. 11). The dry etching effect also tapers the intermediate dielectric films 31-35, leaving tapered intermediate dielectric films 31P-35P as shown in FIG. 11. The dielectric top films 51t-55t, together with the tapered intermediate dielectric films 31P-35P, constitute upper dielectric films 61, 62, 63, 64, 65.

In HDP-CVD, the growth or deposition of the trench-filling dielectric layer 70 and the sputtering or dry etching of the nitride films occur concurrently. Compared with other types of CVD, this process has the advantage of preventing the occurrence of voids (spaces left unfilled with dielectric material) in the trenches 10a-10e, so that a void-free dielectric layer 70 is formed inside the trenches 10a-10e. If, for example, a silicon oxide film is formed as the trench-filling dielectric layer 70, a mixture of silane (SiH₄) and oxygen (O₂) gases may be used as the source gas species of the trench-filling dielectric layer 70, and argon (Ar) gas may be used as the sputtering gas species, but other gaseous species may also be used.

In HDP-CVD it is possible to control the deposition-to-sputtering ratio (D/S ratio), thereby balancing the amount of etching (sputtering) of the dielectric films 31-35, 50 in FIG. 10 against the speed at which the trench-filling dielectric layer 70 is formed. The D/S ratio is defined by the following equation (1):

D/S ratio=(S+D)/S=1+D/S (1)

In equation (1), D indicates the rate of formation of the trench-filling dielectric layer 70 and S indicates the sputtering rate, both rates being expressed in nanometers per second.

If the value of the D/S ratio is too large, the corners of the stress-canceling nitride film 50 in FIG. 10 are inadequately etched, and this nitride film 50 fails to be separated into the dielectric top films 51t-55t and the dielectric base films 51b-55b. As described later, separation of the dielectric base films 51b-55b from the dielectric top films 51t-55t by etching the corners of nitride film 50 is a key to securing good trench isolation performance. It is therefore desirable to limit the D/S ratio to a value greater than unity but equal to or less than four, preferably to a value equal to or less than three. For example, if SiH₄ gas, O₂ gas, and Ar gas are introduced into the reaction chamber at flow rates of 60 sccm, 100 sccm, and 100 sccm, respectively, a D/S ratio less than three can be obtained by supplying 3000-W source RF power and 4000-W bias RF power to the HDP-CVD apparatus, where sccm stands for standard cubic centimeters per minute, W stands for watts, and RF stands for radio frequency.

Although the formation of the trench-filling dielectric layer 70 and the etching of the dielectric films 31-35, 50 are preferably carried out concurrently by HDP-CVD, other methods may be used. In one alternative embodiment, first the dielectric base films 51b-55b and dielectric top films 51t-55t are formed, and then the trench-filling dielectric layer 70 is deposited in a separate process.

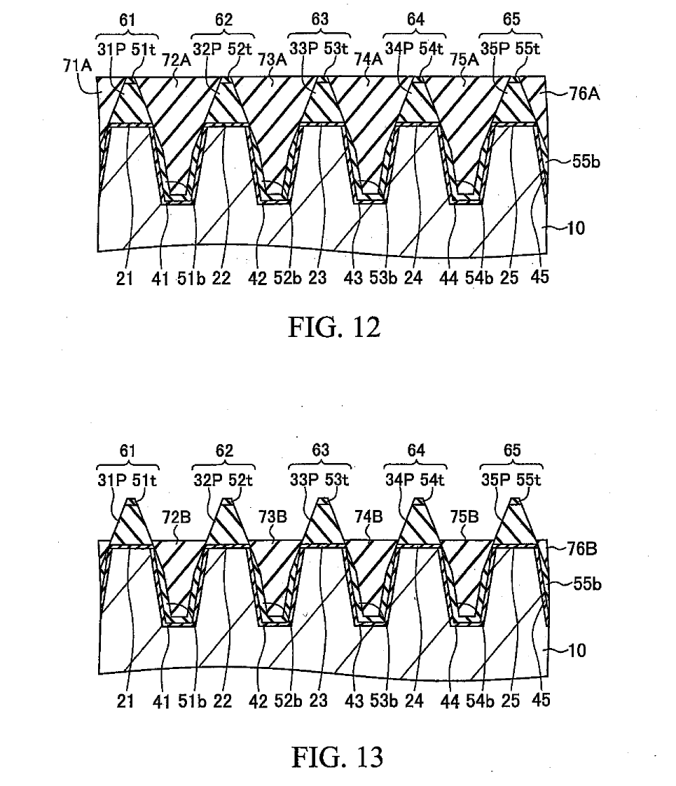

After the trench-filling dielectric layer 70 in FIG. 11 is formed, it is polished and planarized by CMP to expose the dielectric top films 51t-55t. The upper dielectric films 61-65 serve as CMP stopper films. As shown in FIG. 12, this process leaves dielectric layers 71A, 72A, 73A, 74A, 75A, 76A with planarized upper surfaces. The upper surfaces of dielectric layers 71A-76A are then selectively wet-etched to reduce their height, leaving the dielectric layers 72B, 73B, 74B, 75B, 76B shown in FIG. 13. The wet etching time is adjusted so as to expose almost the entire part of the upper dielectric films 61-65, but not to expose any part of the dielectric base films 51b-55b. The resulting dielectric layers 72B-76B fully cover the dielectric base films 51b-55b. If dielectric layers 71A-76A are silicon oxide films, they may be etched by a hydrofluoric acid (HF) solution to form dielectric films 72B-76B.

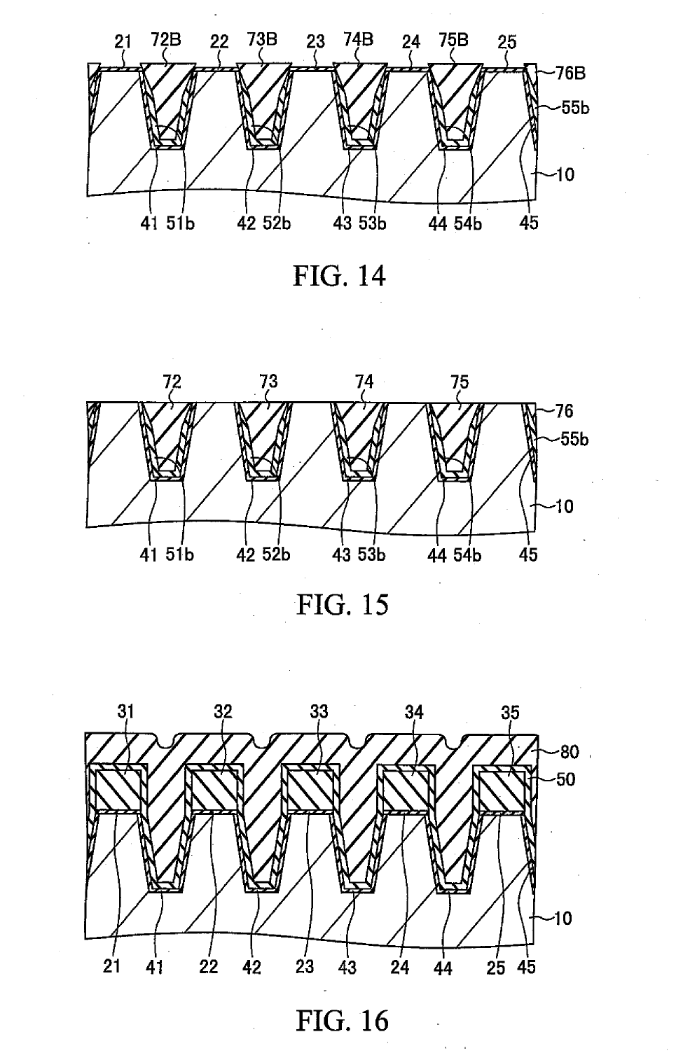

Next, the upper dielectric films 61-65 are removed by wet etching, using dielectric layers 72B-76B as a mask (FIG. 14). If the upper dielectric films 61-65 are silicon nitride films, they may be removed by etching with a phosphoric acid solution. Then the upper portions of dielectric layers 72B-76B and the remaining surface oxide films 21 to 25 are removed by wet etching to complete the trench isolation structure (FIG. 15). As shown in FIG. 15, the insides of the isolation trenches are filled with dielectric layers 72 to 76 formed on the dielectric base films 51b-55b that cover the thermal oxide films 41-45, which are also dielectric.

During subsequent heat treatment, since the dielectric base films 51b-55b produce a stress that cancels the stress produced at the interface between the thermal oxide films 41-45 and the silicon substrate 10, no crystal damage develops from this interface. In addition, since the dielectric base films 51b-55b are completely covered by the dielectric layers 72B-76B in FIG. 13, they are not eroded by the etching process that removes the upper dielectric films 61-65. Accordingly, the resulting trench isolation structure delivers full isolation performance. The key to achieving this full performance is to adjust the amount of etching of the stress-canceling nitride film 50 in the HDP-CVD process so that the dielectric base films 51b-55b taper correctly inside the trenches 10a-10e.

If the D/S ratio is too large in the HDP-CVD process and the dielectric films 31-35, 50 are inadequately etched, the dielectric base films 51b-55b will not form properly inside the trenches 10a-10e. This will be described with reference to a comparative fabrication example.

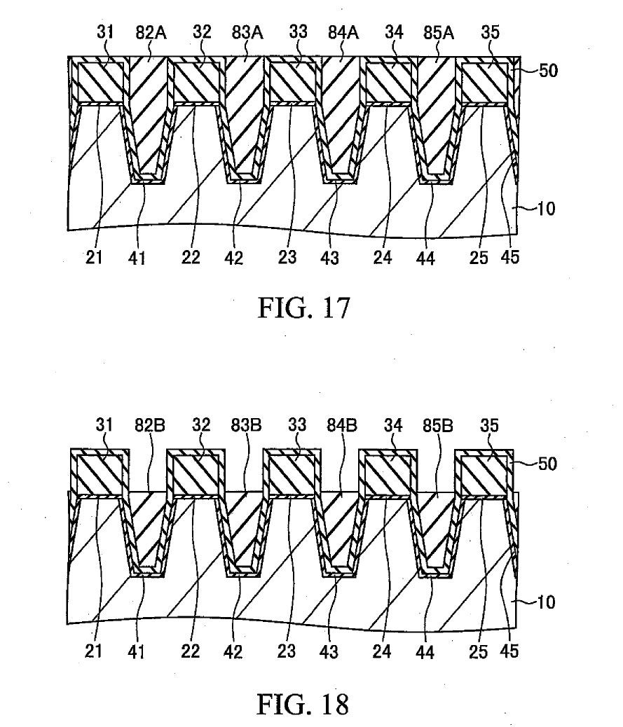

This comparative fabrication process starts with the steps in shown in FIGS. 7 to 10, described above. In the succeeding HDP-CVD process (FIG. 16), a dielectric layer 80 of silicon oxide is deposited on all surfaces, filling the trenches 10a-10e in FIG. 10, but the D/S ratio too large and the dielectric films 31-35, 50 are scarcely etched at all. Thus as shown in FIG. 16, the dielectric films 31-35, 50 are left substantially intact. When the upper surface of the dielectric layer 80 is polished by CMP (FIG. 17), nitride film 50 serves as a stopper film, and trench-filling dielectric layers 82A, 83A, 84A, 85A, 86A with planarized upper surfaces are formed. The trench-filling dielectric layers 82A-86A are then selectively wet-etched to reduce their height, leaving trench-filling dielectric layers 82B, 83B, 84B, 65B (FIG. 18).

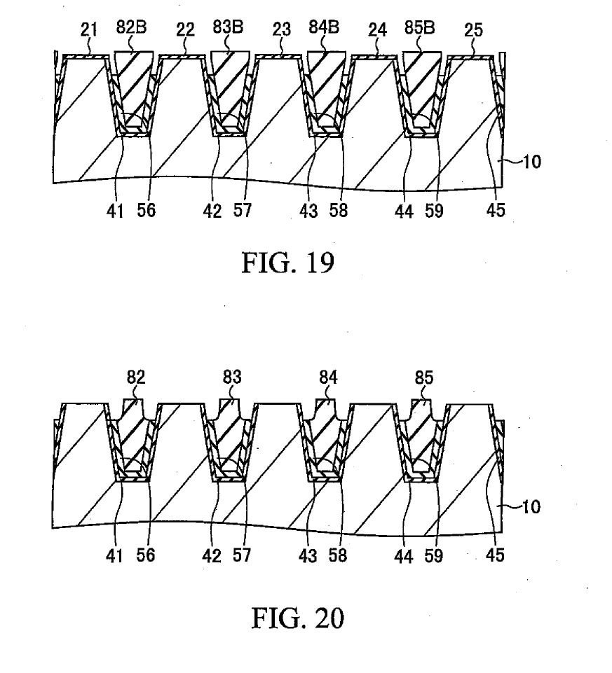

Next, the dielectric films 31-35, 50 are selectively removed by wet etching, using a phosphoric acid solution or other etchant (FIG. 19). Since the part of nitride film 50 in the trenches is not completely covered by the trench-filling dielectric layers 82B to 85B but is continuous with the part of nitride film 50 disposed on dielectric films 31-35, the part of nitride film 50 in the trenches, disposed on the thermal oxide films 41-45, is not protected from the etchant and is partially eroded. As a result, as shown in FIG. 19, dielectric base films 56, 57, 58, 59 are formed but gaps are left between the trench-filling dielectric layers 82B-85B and the thermal oxide films 41-44. When the upper portions of the trench-filling dielectric layers 82B-85B and the surface oxide films 21-25 are wet-etched to complete the trench isolation structure (FIG. 20), the etchant enters the gaps between the trench-filling dielectric layers 82B-85B and the thermal oxide films 41-44 and erodes the side surfaces of the trench-filling dielectric layers 82B-85B so that, as shown in FIG. 20, the dielectric layers 82, 83, 84, 85 left on the thermal oxide films 41-45 and dielectric base films 56-59 inside the isolation trenches do not fill the isolation trenches completely. This may lead to failures such as electrical short circuits when transistor gate wiring is formed later.

When such under-etching is avoided, however, the semiconductor device fabrication method of the first embodiment can prevent the occurrence of crystal damage in the silicon substrate 10 and form a trench isolation structure that gives full isolation performance, as described above.

Another possibility is that the upper portions of the stress-canceling nitride film 50 in FIG. 10 may be completely removed in the HDP-CVD process so that the dielectric top films 51t-55t are not formed. In this case, however, the intermediate dielectric films 31P-35P can assume the function of the non-existent dielectric top films 51t-55t and act as stopper films for the CMP process, particularly if the intermediate dielectric films 31P-35P are formed from the same dielectric material as the stress-canceling nitride film 50.

### Second Embodiment

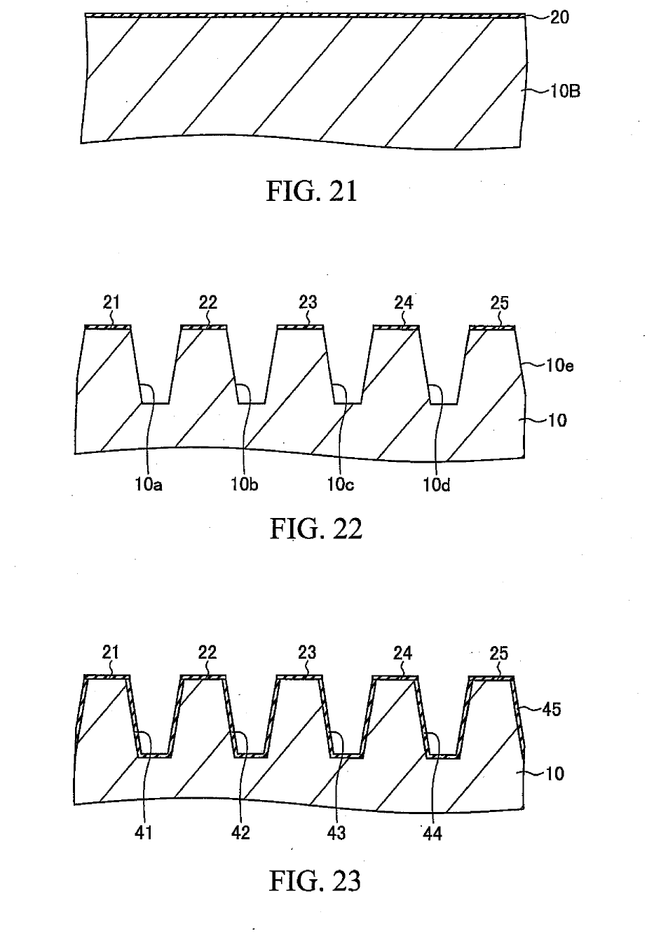

A second semiconductor device fabrication method embodying the invention will now be described with reference to FIGS. 21 to 29.

As in the first embodiment, a surface oxide film 20 is formed on the major surface of a silicon substrate 10B (FIG. 21). Next, a resist mask (not shown) is formed on the surface oxide film 20 by a lithography process, such as photolithography or more specifically ultraviolet lithography, and the surface oxide film 20 and silicon substrate 10B are patterned by dry etching through this mask to form patterned surface oxide films 21-25 and isolation trenches 10a-10e in the silicon substrate 10B (FIG. 22).

Next the inner surfaces of the isolation trenches 10a-10e are thermally oxidized, forming thermal oxide films 41-45 to repair damage caused by the dry etching process (FIG. 23).

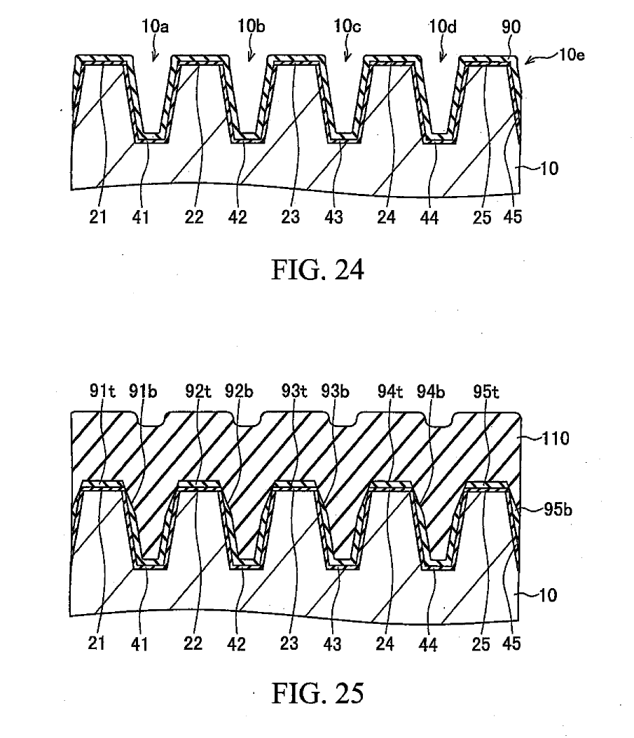

Next a nitride film 90 is deposited as a dielectric stress-canceling film on the surface oxide films 21-25 and thermal oxide films 41-45 by LP-CVD (FIG. 24). This nitride film 90 may be made from the same material as nitride film 50 in the first embodiment, to provide the same stress-canceling function, but its thickness may be in the range from approximately 50 nm to 200 nm.

Next, a trench-filling dielectric layer 110 of a high-dielectric material (e.g., a plasma oxide film) is deposited by HDP-CVD on the entire major surface of the substrate, including the insides of the trenches 10a-10e in FIG. 24. This deposition process also sputters or dry-etches the nitride film 90 in a direction substantially perpendicular to the major surface of the silicon substrate 10. The remaining parts of the nitride film 90 are left as dielectric base films 91b, 92b, 93b, 94b, 95b inside the trenches 10a-10e and dielectric top films 91t, 92t, 93t, 94t, 95t outside the trenches 10a-10e (FIG. 25). To separate the nitride film 90 into dielectric top films 91t-95t and dielectric base films 91b-95b by etching the corners of the nitride film 90, the D/S ratio in the HDP-CVD process is preferably value greater than unity and equal to or less than four or, more preferably, equal to or less than three. As in the first embodiment, if SiH₄ gas, O₂ gas, and Ar gas are introduced into the reaction chamber at flow rates of 60 sccm, 100 sccm, and 100 sccm, respectively, a D/S ratio equal to or less than three can be obtained by supplying 3000-W source RF power and 4000-W bias RF power to the HDP-CVD apparatus.

Instead of the forming the trench-filling dielectric layer 110 and etching the nitride film 90 concurrently by HDP-CVD, first the dielectric base films 91b-95b and dielectric top films 91t-95t may be formed, and then the trench-filling dielectric layer 110 may be deposited in a separate process, as mentioned in the first embodiment.

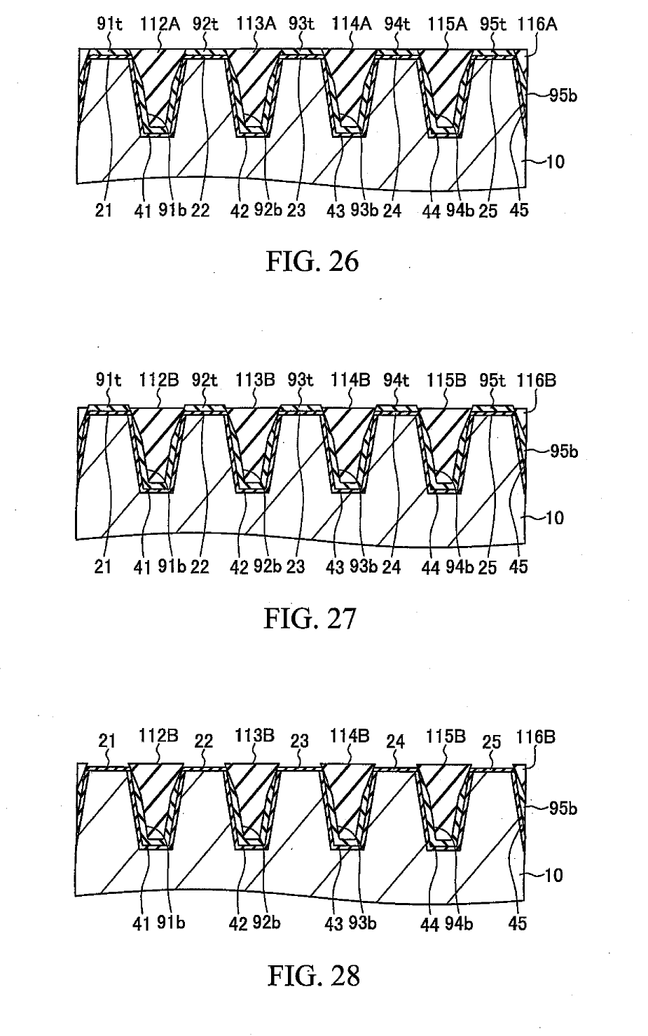

After the trench-filling dielectric layer 110 is formed in FIG. 25, its upper surface is polished and planarized by CMP to expose the dielectric top films 91t-95t (FIG. 26). The dielectric top films 91t-95t serve as CMP stopper films. As shown in FIG. 26, this process leaves trench-filling dielectric layers 112A, 113A, 114A, 115A, 116A with planarized upper surfaces. The upper surfaces of these dielectric layers 112A-116A are then selectively wet-etched to reduce their height, leaving trench-filling dielectric layers 112B-116B (FIG. 27). The wet etching time is adjusted so as not to expose any part of the dielectric base films 91b-95b. The resulting trench-filling dielectric layers 112B-116B fully cover the dielectric base films 91b-95b. If the dielectric layers 112A-116A are made of silicon oxide, a wet etching solution of hydrofluoric acid may be used to reduce them to dielectric layers 112B-116B.

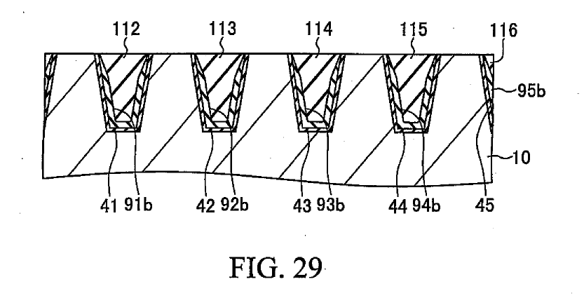

Next, the dielectric top films 91t-95t are removed by wet etching, using trench-filling dielectric layers 112B-116B as a mask (FIG. 28). If the dielectric top films 91t-95t are silicon nitride films, a wet etching solution of phosphoric acid may be used. Then the upper portions of the trench-filling dielectric layers 112B-116B and the surface oxide films 21-25 are removed by wet etching to complete the trench isolation structure (FIG. 29). As shown in FIG. 29, the insides of the isolation trenches are filled with dielectric layers 112, 113, 114, 115, 116 formed on the dielectric base films 91b-95b that cover the thermal oxide films 41-45, which are also dielectric.

During subsequent heat treatment, since the dielectric base films 91b-95b produce a stress that cancels the stress produced at the interface between the thermal oxide films 41-45 and the silicon substrate 10, no crystal damage develops from that interface. In addition, the dielectric base films 91b-95b are completely covered by the trench-filling dielectric layers 112B-116B in FIG. 27, so they are not eroded by the etching process that removes the dielectric top films 91t-95t. Accordingly, in the final trench isolation structure, the trenches are completely filled with dielectric material and give full isolation performance.

In the second embodiment, the trenches 10a-10d are formed immediately after the formation of the surface oxide film 20 (FIG. 21), and the stress-canceling nitride film 90 is deposited directly on the patterned surface oxide films 21-25 without forming the intermediate dielectric film 30 shown in FIG. 7. This results in a lower fabrication cost than in the first embodiment, but to avoid exposure of the dielectric base films 91b-95b, the chemical mechanical planarization (CMP) process in FIG. 26 must stop reliably at the dielectric top films 91t-95t. In contrast, in the first embodiment, the intermediate dielectric films 31P-35P derived from the intermediate dielectric film 30 are formed as shown in FIG. 12. Since these dielectric films 31P-35P allow the dielectric top films 51t-55t to have sufficient heights above the top of the semiconductor substrate 10, the dielectric top films 51t-55t as CMP stopper films can be used to halt the CMP process in FIG. 12 before it exposes the dielectric base films 51t-55t.

Those skilled in the art will recognize that further variations are possible within the scope of the invention, which is defined in the appended claims.

What is claimed is:

1. A semiconductor device fabrication method comprising:
forming a surface oxide film on a major surface of a semiconductor substrate;
forming a trench by patterning the surface oxide film and semiconductor substrate;
forming a thermal oxide film on inner surfaces of the trench, the thermal oxide film exerting a first stress on the semiconductor substrate when heated;
depositing a dielectric stress-canceling film on the surface oxide film and the thermal oxide film, the dielectric stress-canceling film exerting a second stress on the thermal oxide film in a direction canceling the first stress when heated;
etching part of the dielectric stress-canceling film, leaving a dielectric base film inside the trench and a dielectric top film outside the trench;
depositing a trench-filling dielectric layer covering the dielectric base film and the dielectric top film;
removing an upper part of the trench-filling dielectric layer to expose the dielectric top film; and
removing the dielectric top film by selective etching, using the trench-filling dielectric layer as an etching mask.

2. The semiconductor device fabrication method of claim 1, wherein said etching part of the dielectric stress-canceling film includes dry-etching the dielectric stress-canceling film in a direction perpendicular to the major surface of the semiconductor substrate.

3. The semiconductor device fabrication method of claim 2, wherein said dry-etching the dielectric stress-canceling film is performed concurrently with said depositing a dielectric stress-canceling film by a high-density plasma chemical vapor deposition process.

4. The semiconductor device fabrication method of claim 3, wherein the high-density plasma chemical vapor deposition process has a deposition rate D, a sputtering rate S, and a D/S ratio of at most four, the D/S ratio being defined as:
(S+D)/S.

5. The semiconductor device fabrication method of claim 4, wherein the D/S ratio is greater than unity.

6. The semiconductor device fabrication method of claim 5, wherein the D/S ratio is at most three.

7. The semiconductor device fabrication method of claim 4, wherein the high-density plasma chemical vapor deposition process uses silane and oxygen as source gases and argon as a sputtering gas.

8. The semiconductor device fabrication method of claim 7, wherein the high-density plasma chemical vapor deposition process has a silane flow rate of sixty standard cubic centimeters per minute, an oxygen flow rate of one hundred standard cubic centimeters per minute, and an argon flow rate of one hundred standard cubic centimeters per minute.

9. The semiconductor device fabrication method of claim 1, further comprising removing the surface oxide film and an adjacent part of the trench-filling dielectric layer by etching after removing the dielectric top film.

10. The semiconductor device fabrication method of claim 1, wherein said removing an upper part of the trench-filling dielectric layer includes planarizing an upper surface of the trench-filling dielectric layer which is performed by a chemical mechanical polishing process using the dielectric top film as a stopper film.

11. The semiconductor device fabrication method of claim 1, further comprising:
forming an intermediate dielectric film on the surface oxide film before forming the trench;
patterning the intermediate dielectric film together with the surface oxide film and the semiconductor substrate thereby to form the trench; and
removing the intermediate dielectric film together with the dielectric top film by said selective etching; wherein
the dielectric stress-canceling film is deposited directly on the intermediate dielectric film and the thermal oxide film, the intermediate dielectric film being interposed between the dielectric stress-canceling film and the surface oxide film; and
the dielectric top film is formed by etching part of the intermediate dielectric film together with said part of the dielectric stress-canceling film.

12. The semiconductor device fabrication method of claim 11, wherein the intermediate dielectric film is at least fifty nanometers thick and at most two hundred nanometers thick.

13. The semiconductor device fabrication method of claim 11, wherein the dielectric stress-canceling film is at least twenty nanometers thick and at most one hundred nanometers thick.

14. The semiconductor device fabrication method of claim 11, wherein the intermediate dielectric film and the dielectric stress-canceling film comprise mutually identical materials.

15. The semiconductor device fabrication method of claim 1, wherein the surface oxide film is patterned directly after the forming of the oxide film and the dielectric stress-canceling film is deposited directly on the surface oxide film.

16. The semiconductor device fabrication method of claim 15, wherein the dielectric stress-canceling film is at least fifty nanometers thick and at most two hundred nanometers thick.

17. The semiconductor device fabrication method of claim 1, wherein the dielectric stress-canceling film is a nitride film.
